(19) United States
(12) Patent Application Publication
(10) Pub. No.: US 2026/0025126 A1
(43) Pub. Date: Jan. 22, 2026

(54) Device and Method for Reducing a Settling Time of an Output of the Same

(71) Applicant: Taiwan Semiconductor Manufacturing Company, Ltd., Hsinchu (TW)

(72) Inventors: Hamza Yacoub Al-Maharmeh, Hsinchu (TW); Manoj Bharat Vasekar, Hsinchu (TW); Mei-Chen Chuang, Hsinchu (TW); Shenggao Li, Hsinchu (TW)

(21) Appl. No.: 18/779,308

(22) Filed: Jul. 22, 2024

(51) Int. Cl. H03K 3/011; G05F 3/26; H03K 3/0233

(52) U.S. Cl. CPC H03K 3/011; G05F 3/262; H03K 3/02335

(57) ABSTRACT

A device includes a comparator circuit and a current generator circuit. The comparator circuit, responsive to a current, receives an input signal and a reference signal, compares the input signal with the reference signal, and generates an output signal that indicates the result of comparison. The current generator circuit includes a current mirror circuit and a current booster circuit. The current mirror circuit generates the current. The current booster circuit amplifies the current from an initial current value to a higher current value and maintains the current at the higher current value over a predetermined duration of time. A method for reducing a settling time of an output of the device is also disclosed.

### BACKGROUND

Comparators compare an input voltage signal against a reference voltage signal and generate an output voltage signal that indicates the result of comparison. Certain comparators make a decision in a relatively short duration of time. For example, a continuous-time comparator continuously monitors the input voltage signal and decides at the moment the input voltage signal crosses the level of the reference voltage signal. This is in contrast to a clocked comparator that provides an output voltage signal at a transition of a clock signal. The output voltage signal of the continuous-time comparator may be processed by an analog-to-digital converter (ADC) to convert an analog representation of, e.g., temperature, pressure, light intensity, and the like, into a digital format.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic circuit diagram illustrating another exemplary device in accordance with various embodiments of the present disclosure;

FIG. 3 is a schematic circuit diagram illustrating another exemplary device in accordance with various embodiments of the present disclosure;

FIG. 4 is a schematic circuit diagram illustrating another exemplary device in accordance with various embodiments of the present disclosure;

FIG. 5 is a schematic circuit diagram illustrating another exemplary device in accordance with various embodiments of the present disclosure;

FIG. 6 is a schematic circuit diagram illustrating another exemplary device in accordance with various embodiments of the present disclosure;

FIG. 7 is a schematic circuit diagram illustrating another exemplary device in accordance with various embodiments of the present disclosure;

FIG. 8 is a schematic circuit diagram illustrating another exemplary device in accordance with various embodiments of the present disclosure;

FIG. 9 is a schematic circuit diagram illustrating another exemplary device in accordance with various embodiments of the present disclosure;

FIG. 10 is a flowchart of an exemplary method for reducing a settling time of an output of a device in accordance with various embodiments of the present disclosure;

FIG. 11 is a flowchart of another exemplary method for reducing a settling time of an output of a device in accordance with various embodiments of the present disclosure; and

FIG. 12 is a flowchart of an exemplary method for designing a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As noted above, comparators compare an input voltage signal against a reference voltage signal and generate an output voltage signal that indicates the result of comparison, either a high or low logical state. For example, a continuous-time comparator continuously monitors the input voltage signal and decides at the moment the input voltage signal crosses the level of the reference voltage signal. The output voltage signal of the continuous-time comparator may be processed by an analog-to-digital converter (ADC) to convert an analog representation of, e.g., temperature, pressure, light intensity, and the like, into a digital format. However, the duration (or latency) of the settling time it takes for the output voltage signal to stabilize and to provide an accurate comparison result may in some instances be undesirably long. This may cause the analog-to-digital conversion to be less efficient than desired.

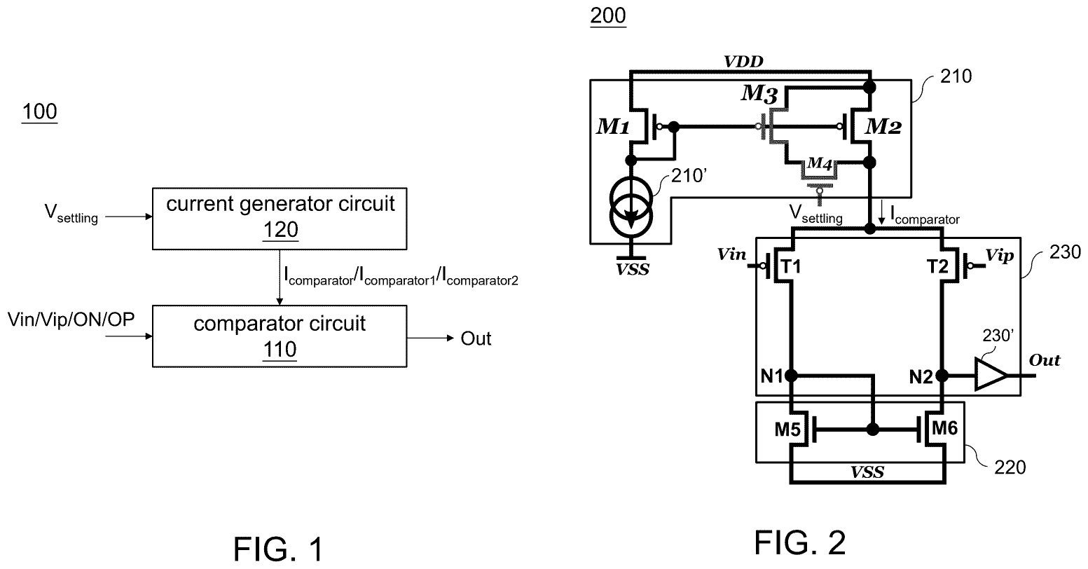

Certain systems and methods, as described herein, can mitigate these issues by employing a current booster circuit that amplifies (boosts or increases) a current flowing through a continuous-time comparator over a predetermined duration of time. This may reduce a settling time of an output voltage signal of the continuous-time comparator (e.g., by up to 75% or more). In further detail, FIG. 1 is a schematic block diagram illustrating an exemplary device 100, e.g., a continuous-time comparator, in accordance with various embodiments of the present disclosure.

As illustrated in FIG. 1, the example device 100 includes a comparator circuit 110 and a current generator circuit 120. The comparator circuit 110 receives input signals, e.g., voltage signals (Vin, Vip, ON, OP), is responsive to a current (I_{comparator}, I_{comparator1}, I_{comparator2}), compares an input voltage signal (Vin) with a reference voltage signal (Vip), and generates an output signal, e.g., voltage signal (Out), that indicates the result of comparison. In certain embodiments, the output voltage signal (Out) of the device 100 may be processed by an ADC to convert an analog representation of, e.g., temperature, pressure, light intensity, and the like, into a digital format.

The current generator circuit 120 generates a current, e.g., current (I_{comparator}), that flows to (or from) the comparator circuit 130. In this exemplary embodiment, the current generator circuit 120 adjusts a current value of the current (I_{comparator}) to shorten the duration of the settling time it takes for the output voltage signal (Out) to stabilize and to provide an accurate comparison result, in a manner that will be described in detail hereinafter.

Example supporting circuitry for the device 100 is depicted in FIG. 2. It is understood that this circuitry is provided by way of example, not by limitation, and other suitable device 100 circuitry are within the scope of the present disclosure. FIG. 2 is a schematic circuit diagram illustrating an exemplary device 200 in accordance with various embodiments of the present disclosure. As illustrated in FIG. 2, the example device 200 includes a current generator circuit, e.g., current generator circuit 120, and a comparator circuit 230. The current generator circuit includes a first current mirror circuit 210 and a second current mirror circuit 220. The first current mirror circuit 210 includes first-fourth transistors (M1-M4) and a current source circuit 210′. In this exemplary embodiment, the transistors (M3, M4) constitute a current booster circuit configured to amplify (boost or increase) the current (I_{comparator}) that flows to the comparator circuit 230.

Each transistor (M1-M4) is a p-type metal-oxide-semiconductor (PMOS) transistor. The first source/drain terminal of the transistor (M1), the first source/drain terminal of the transistor (M2), and the first source/drain terminal of the transistor (M3) are connected to each other and to a supply voltage (VDD). The gate terminal of the transistor (M1), the gate terminal of the transistor (M2), and the gate terminal of the transistor (M3) are connected to each other and to the second source/drain terminal of the transistor (M1). The transistor (M4) has a first source/drain terminal connected to the second source/drain terminal of the transistor (M2) and a second source/drain terminal connected to the second source/drain terminal of the transistor (M3). The current source circuit 210′ is connected between the second source/drain terminal of the transistor (M1) and a supply voltage (Vss) (or electrical ground).

The second current mirror circuit 220 includes transistors (M5, M6), each of which is an n-type metal-oxide-semiconductor (NMOS) transistor. The first source/drain terminal of the transistor (M5) and the first source/drain terminal of the transistor (M6) are connected to each other and to the supply voltage (Vss) (or electrical ground). The gate terminal of the transistor (M5) and the gate terminal of the transistor (M6) are connected to each other and to the second source/drain terminal of the transistor (M5) at node (N1).

The comparator circuit 230 is connected between the first and second current mirror circuits 210, 220. For example, the comparator circuit 230 includes transistors (T1, T2) and a buffer circuit 230′. Each transistor (T1, T2) is a PMOS transistor. The first source/drain terminal of the transistor (T1) and the first source/drain terminal of the transistor (T2) are connected to each other, to the second source/drain terminal of the transistor (M2), and to the second source/drain terminal of the transistor (M4). The second source/drain terminal of the transistor (T1) is connected to the node (N1). The gate terminal of the transistor (T1) serves as an inverted (or a non-inverted) input of the device 200. The second source/drain terminal of the transistor (T2) and the second source/drain terminal of the transistor (M6) are connected to each other at node (N2). The gate terminal of the transistor (T2) serves as a non-inverted (or an inverted) input of the device 200. The buffer circuit 230′ has an input terminal connected to the node (N2) and an output terminal that serves as an output of the device 200.

In operation, the device 100 receives the supply voltage (VDD). Consequently, the current source circuit 210′ generates a substantially constant current, whereby a transistor current flows through the transistor (M1). The transistor (M2) mirrors the transistor current flowing through the transistor (M1). Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). Thereafter, the buffer circuit 230′ generates an output voltage signal (Out) that indicates the result of comparison between the input voltage signal (Vin) and the reference voltage signal (Vip). At this time, the transistor (M4) is turned on by a settling voltage signal (V_{ettling}). This amplifies (boosts or increases) the current (I_{comparator}) flowing to the comparator circuit 230 from an initial current value to a higher current value. The higher current value of the current (I_{comparator}) is maintained over a predetermined duration of time. As a result, the duration of the settling time it takes for the output voltage signal (Out) to stabilize and to provide an accurate comparison result is reduced, improving the efficiency of the device 200. After the predetermined duration of time elapses, the settling voltage signal (V_{settling}) goes high. This turns the transistor (M4) off, causing the current (I_{comparator}) to decrease back to its initial current value. Meanwhile, the device 200 continues with the comparison of the input voltage signal (Vin) to the reference voltage signal (Vip) and generates the output voltage signal (Out).

Although the current booster circuit of the device 200 is exemplified using transistors (M3, M4), the current booster circuit of the device 200 may take any form in other embodiments so long as it achieves the intended purpose of amplifying the current (I_{comparator}) over a predetermined duration of time, as described above. For example, in an alternative embodiment, the transistor (M4) may be in the form of any switch circuit that selectively connects the second source/drain terminal of the transistor (M3) to the second source/drain terminal of the transistor (M2).

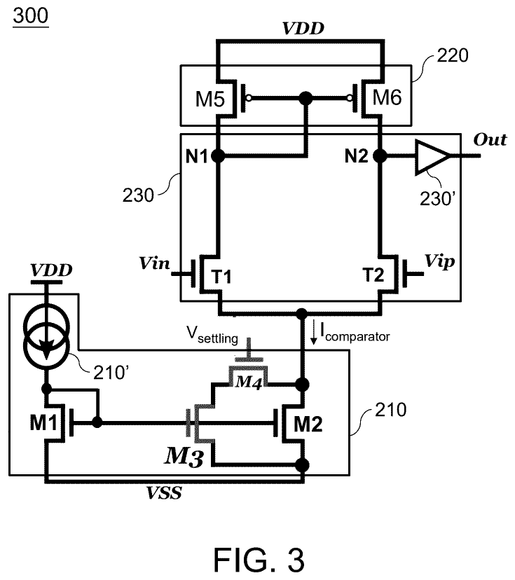

FIG. 3 is a schematic circuit diagram illustrating another exemplary device 300 in accordance with various embodiments of the present disclosure. As illustrated in FIG. 3, the example device 300 differs from the device 200 in that the first source/drain terminal of the transistor (M1), the first source/drain terminal of the transistor (M2), and the first source/drain terminal of the transistor (M3) are connected to the supply voltage (Vss) (or an electrical ground). The current source circuit 210′ is connected between the second source/drain terminal of the transistor (M1) and the supply voltage (VDD). The first source/drain terminal of the transistor (M5) and the first source/drain terminal of the transistor (M6) are connected to the supply voltage (VDD).

Because the operations of the device 300 are similar to those described hereinabove in connection with the device 200, a detailed description of the same will be dispensed with herein for the sake of brevity.

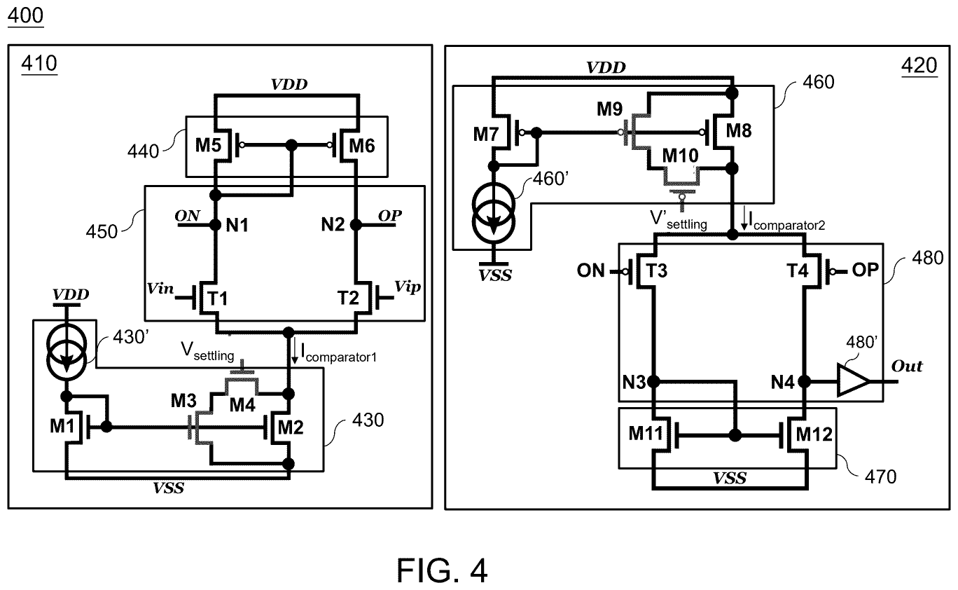

Although the device 200, 300 is exemplified as a single stage continuous-time comparator, multi-stage continuous-time comparators are also contemplated herein in other embodiments. For example, FIG. 4 is a schematic circuit diagram illustrating another exemplary device 400 in accordance with various embodiments of the present disclosure. As illustrated in FIG. 4, the example device 400 differs from the device 200 in that the device 400 is a two-stage continuous-time comparator and includes a first device stage 410 and a second device stage 420. In this exemplary embodiment, one of the first and second device stages 410, 420 has a high gain, e.g., greater than 30 dB and the other of the first and second device stages 410, 420 is for limiting a bandwidth, e.g., 300 MHz.

The first device stage 410 includes a current generator circuit, e.g., current generator circuit 120, and a comparator circuit 450. The current generator circuit includes a first current mirror circuit 430 and a second current mirror circuit 440. The first current mirror circuit 430 includes first-fourth transistors (M1-M4) and a current source circuit 430′. In this exemplary embodiment, the transistors (M3, M4) constitute a current booster circuit configured to amplify (boost or increase) the current (I_{comparator1}) that flows to the comparator circuit 450.

Each transistor (M1-M4) is an NMOS transistor. The first source/drain terminal of the transistor (M1), the first source/drain terminal of the transistor (M2), and the first source/drain terminal of the transistor (M3) are connected to each other and to the supply voltage (Vss) (or electrical ground). The gate terminal of the transistor (M1), the gate terminal of the transistor (M2), and the gate terminal of the transistor (M3) are connected to each other and to the second source/drain terminal of the transistor (M1). The transistor (M4) has a first source/drain terminal connected to the second source/drain terminal of the transistor (M2) and a second source/drain terminal connected to the second source/drain terminal of the transistor (M3). The current source circuit 430′ is connected between the second source/drain terminal of the transistor (M1) and the supply voltage (VDD).

The second current mirror circuit 440 includes transistors (M5, M6), each of which is a PMOS transistor. The first source/drain terminal of the transistor (M5) and the first source/drain terminal of the transistor (M6) are connected to each other and to the supply voltage (VDD). The gate terminal of the transistor (M5) and the gate terminal of the transistor (M6) are connected to each other and to the second source/drain terminal of the transistor (M5) at node (N1).

The comparator circuit 450 is connected between the first and second current mirror circuits 430, 440. For example, the comparator circuit 450 includes transistors (T1, T2), each of which is an NMOS transistor. The first source/drain terminal of the transistor (T1) and the first source/drain terminal of the transistor (T2) are connected to each other, to the second source/drain terminal of the transistor (M2), and to the second source/drain terminal of the transistor (M4). The second source/drain terminal of the transistor (T1) is connected to the node (N1). The gate terminal of the transistor (T1) serves as an inverted (or a non-inverted) input of the device 400. The second source/drain terminal of the transistor (T2) and the second source/drain terminal of the transistor (M6) are connected to each other at node (N2). The gate terminal of the transistor (T2) serves as a non-inverted (or an inverted) input of the device 400.

The second device stage 420 includes a current generator circuit, e.g., current generator circuit 120, and a comparator circuit 480. The current generator circuit includes a first current mirror circuit 460 and a second current mirror circuit 470. The first current mirror circuit 460 includes first-fourth transistors (M7-M10) and a current source circuit 460′. In this exemplary embodiment, the transistors (M9, M10) constitute a current booster circuit configured to amplify (boost or increase) the current (I_{comparator2}) that flows to the comparator circuit 480.

Each transistor (M7-M10) is a PMOS transistor. The first source/drain terminal of the transistor (M7), the first source/drain terminal of the transistor (M8), and the first source/drain terminal of the transistor (M9) are connected to each other and to the supply voltage (VDD). The gate terminal of the transistor (M7), the gate terminal of the transistor (M8), and the gate terminal of the transistor (M9) are connected to each other and to the second source/drain terminal of the transistor (M7). The transistor (M10) has a first source/drain terminal connected to the second source/drain terminal of the transistor (M8) and a second source/drain terminal connected to the second source/drain terminal of the transistor (M9). The current source circuit 460′ is connected between the second source/drain terminal of the transistor (M7) and the supply voltage (Vss) (or electrical ground).

The second current mirror circuit 470 includes transistors (M11, M12), each of which is an NMOS transistor. The first source/drain terminal of the transistor (M11) and the first source/drain terminal of the transistor (M12) are connected to each other and to the supply voltage (Vss) (or electrical ground). The gate terminal of the transistor (M11) and the gate terminal of the transistor (M12) are connected to each other and to the second source/drain terminal of the transistor (M11) at node (N3).

The comparator circuit 480 is connected between the first and second current mirror circuits 460, 470. For example, the comparator circuit 480 includes transistors (T3, T4) and a buffer circuit 480′. Each transistor (T3, T4) is a PMOS transistor. The first source/drain terminal of the transistor (T3) and the first source/drain terminal of the transistor (T4) are connected to each other, to the second source/drain terminal of the transistor (M8), and to the second source/drain terminal of the transistor (M10). The second source/drain terminal of the transistor (T3) is connected to the node (N3). The gate terminal of the transistor (T3) is connected to the node (N1). The second source/drain terminal of the transistor (T4) and the second source/drain terminal of the transistor (M12) are connected to each other at node (N4). The gate terminal of the transistor (T4) is connected to the node (N2). The buffer circuit 480′ has an input terminal connected to the node (N4) and an output terminal that serves as an output of the device 400.

In operation, the device 400 receives the supply voltage (VDD). Consequently, the current source circuits 430′, 460′ each generate a substantially constant current, whereby a transistor current flows through a respective transistor (M1, M7). The transistors (M2, M8) mirror the transistor currents through the transistors (M1, M7), respectively. Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). As a result, voltage signals (ON, OP), each of which corresponds to a respective one of the voltage signals (Vin, Vip), appear at the nodes (N1, N2), respectively.

Subsequently, the transistor (T3) receives the voltage signal (ON) at the gate terminal thereof, whereas the gate terminal of the transistor (T4) receives the voltage signal (OP). Next, the transistor (M11) generates a transistor current that flows therethrough and that is mirrored by the transistor (M12). Thereafter, the buffer circuit 480′ generates an output voltage signal (Out) that indicates the result of comparison between the input voltage signal (Vin) and the reference voltage signal (Vip). At this time, the transistors (M4, M10) are turned on by a settling voltage signal (V_{settling}) and an inverted version of the settling voltage signal (V_{settling}), respectively. This amplifies the current (I_{comparator1}, I_{comparator2}) flowing to the comparator circuit 450, 480 from an initial current value to a higher current value. The higher current value of the current (I_{comparator1}, I_{comparator2}) is maintained over a predetermined duration of time. As a result, the duration of the settling time it takes for the output voltage signal (Out) to stabilize and to provide an accurate comparison result is reduced, improving the efficiency of the device 400. After the predetermined duration of time elapses, the settling voltage signal V_{settling} goes low (and the inverted version of the settling voltage signal V_{settling} goes high). This turns the transistor (M4, M10) off, causing the current (I_{comparator1}, I_{comparator2}) to decrease back to its initial current value. Meanwhile, the device 400 continues with the comparison of the input voltage signal (Vin) to the reference voltage signal (Vip) and generates the output voltage signal (Out).

Although the current booster circuit of the device stage 410 is exemplified using transistors (M3, M4) and the current booster circuit of the device stage 420 is exemplified using transistors (M9, M10), the current booster circuit of each device stage 410, 420 may take any form in other embodiments so long as it achieves the intended purpose of amplifying the current (I_{comparator1}, I_{comparator2}) over a predetermined duration of time, as described above. For example, in an alternative embodiment, the transistor (M4, M10) may be in the form of any switch circuit that selectively connects the second source/drain terminal of the transistor (M3, M9) to the second source/drain terminal of the transistor (M2, M8).

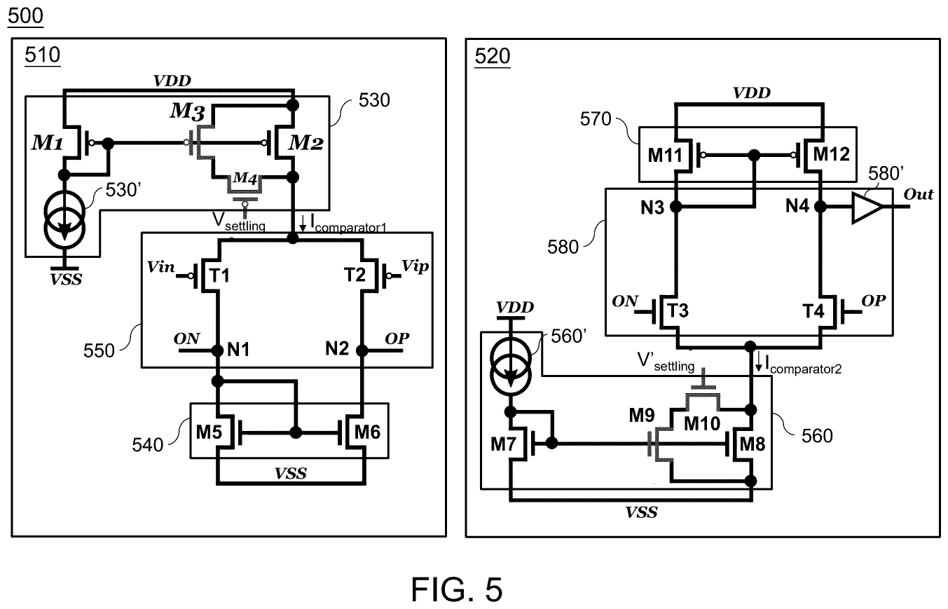

FIG. 5 is a schematic circuit diagram illustrating another exemplary device 500 in accordance with various embodiments of the present disclosure. As illustrated in FIG. 5, the example device 500 differs from the device 200 in that the device 500 is a two-stage continuous-time comparator and includes a first device stage 510 and a second device stage 520. In this exemplary embodiment, one of the first and second device stages 510, 520 has a high gain and the other of the first and second device stages 510, 520 is for limiting a bandwidth.

The first device stage 510 includes a current generator circuit, e.g., current generator circuit 120, and a comparator circuit 550. The current generator circuit includes a first current mirror circuit 530 and a second current mirror circuit 540. The first current mirror circuit 530 includes first-fourth transistors (M1-M4) and a current source circuit 530′. In this exemplary embodiment, the transistors (M3, M4) constitute a current booster circuit configured to amplify (boost or increase) the current (I_{comparator1}) that flows to the comparator circuit 550.

Each transistor (M1-M4) is a PMOS transistor. The first source/drain terminal of the transistor (M1), the first source/drain terminal of the transistor (M2), and the first source/drain terminal of the transistor (M3) are connected to each other and to the supply voltage (VDD). The gate terminal of the transistor (M1), the gate terminal of the transistor (M2), and the gate terminal of the transistor (M3) are connected to each other and to the second source/drain terminal of the transistor (M1). The transistor (M4) has a first source/drain terminal connected to the second source/drain terminal of the transistor (M2) and a second source/drain terminal connected to the second source/drain terminal of the transistor (M3). The current source circuit 530′ is connected between the second source/drain terminal of the transistor (M1) and the supply voltage (Vss) (or electrical ground).

The second current mirror circuit 540 includes transistors (M5, M6), each of which is an NMOS transistor. The first source/drain terminal of the transistor (M5) and the first source/drain terminal of the transistor (M6) are connected to each other and to the supply voltage (Vss) (or electrical ground). The gate terminal of the transistor (M5) and the gate terminal of the transistor (M6) are connected to each other and to the second source/drain terminal of the transistor (M5) at node (N1).

The comparator circuit 550 is connected between the first and second current mirror circuits 530, 540. For example, the comparator circuit 550 includes transistors (T1, T2), each of which is a PMOS transistor. The first source/drain terminal of the transistor (T1) and the first source/drain terminal of the transistor (T2) are connected to each other, to the second source/drain terminal of the transistor (M2), and to the second source/drain terminal of the transistor (M4). The second source/drain terminal of the transistor (T1) is connected to the node (N1). The gate terminal of the transistor (T1) serves as an inverted (or a non-inverted) input of the device 500. The second source/drain terminal of the transistor (T2) and the second source/drain terminal of the transistor (M6) are connected to each other at node (N2). The gate terminal of the transistor (T2) serves as a non-inverted (or an inverted) input of the device 500.

The second device stage 520 includes a current generator circuit, e.g., current generator circuit 120 and a comparator circuit 580. The current generator circuit includes a first current mirror circuit 560 and a second current mirror circuit 570. The first current mirror circuit 560 includes first-fourth transistors (M7-M10) and a current source circuit 560′. In this exemplary embodiment, the transistors (M9, M10) constitute a current booster circuit configured to amplify (boost or increase) the current (I_{comparator2}) that flows to the comparator circuit 580.

Each transistor (M7-M10) is an NMOS transistor. The first source/drain terminal of the transistor (M7), the first source/drain terminal of the transistor (M8), and the first source/drain terminal of the transistor (M9) are connected to each other and to the supply voltage (VSS) (or electrical ground). The gate terminal of the transistor (M7), the gate terminal of the transistor (M8), and the gate terminal of the transistor (M9) are connected to each other and to the second source/drain terminal of the transistor (M7). The transistor (M10) has a first source/drain terminal connected to the second source/drain terminal of the transistor (M8) and a second source/drain terminal connected to the second source/drain terminal of the transistor (M9). The current source circuit 560′ is connected between the second source/drain terminal of the transistor (M7) and the supply voltage (VDD).

The second current mirror circuit 570 includes transistors (M11, M12), each of which is a PMOS transistor. The first source/drain terminal of the transistor (M11) and the first source/drain terminal of the transistor (M12) are connected to each other and to the supply voltage (VDD). The gate terminal of the transistor (M11) and the gate terminal of the transistor (M12) are connected to each other and to the second source/drain terminal of the transistor (M11) at node (N3).

The comparator circuit 580 is connected between the first and second current mirror circuits 560, 570. For example, the comparator circuit 580 includes transistors (T3, T4) and a buffer circuit 580′. Each transistor is an NMOS transistor. The first source/drain terminal of the transistor (T3) and the first source/drain terminal of the transistor (T4) are connected to each other, to the second source/drain terminal of the transistor (M8), and to the second source/drain terminal of the transistor (M10). The second source/drain terminal of the transistor (T3) is connected to the node (N3). The gate terminal of the transistor (T3) is connected to the node (N1). The second source/drain terminal of the transistor (T4) and the second source/drain terminal of the transistor (M12) are connected to each other at node (N4). The gate terminal of the transistor (T4) is connected to the node (N2). The buffer circuit 580′ has an input terminal connected to the stage node (N4) and an output terminal that serves as an output of the device 500.

In operation, the device 500 receives the supply voltage (VDD). Consequently, the current source circuits 430′, 460′ each generate a substantially constant current, whereby a transistor current flows through a respective transistor (M1, M7). The transistors (M2, M8) mirror the transistor currents through the transistors (M1, M7), respectively. Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). As a result, voltage signals (ON, OP), each of which corresponds to a respective one of the voltage signals (Vin, Vip), appear at the nodes (N1, N2), respectively.

Subsequently, the transistor (T3) receives the voltage signal (ON) at the gate terminal thereof, whereas the gate terminal of the transistor (T4) receives the voltage signal (OP). Next, the transistor (M11) generates a transistor current that flows therethrough and that is mirrored by the transistor (M12). Thereafter, the buffer circuit 580′ generates an output voltage signal (Out) that indicates the result of comparison between the input voltage signal (Vin) and the reference voltage signal (Vip). At this time, each transistor (M4, M10) are turned on by a settling voltage signal (V_{settling}) and an inverted version of the settling voltage signal (V_{settling}), respectively. This amplifies the current (I_{comparator1}, I_{comparator2}) flowing to the comparator circuit 550, 580 from an initial current value to a higher current value. The higher current value of the current (I_{comparator1}, I_{comparator2}) is maintained over a predetermined duration of time. As a result, the duration of the settling time it takes for the output voltage signal (Out) to stabilize and to provide an accurate comparison result is reduced, improving the efficiency of the device 500. After the predetermined duration of time elapses, the settling voltage signal V_{settling} goes high (and the inverted version of the settling voltage signal V_{settling} goes low). This turns the transistor (M4, M10) off, causing the current (I_{comparator1}, I_{comparator2}) to decrease back to its initial current value. Meanwhile, the device 500 continues with the comparison of the input voltage signal (Vin) to the reference voltage signal (Vip) and generates the output voltage signal (Out).

Although the current booster circuit of the device stage 510 is exemplified using transistors (M3, M4) and the current booster circuit of the device stage 520 is exemplified using transistors (M9, M10), the current booster circuit of each device stage 510, 520 may take any form in other embodiments so long as it achieves the intended purpose of amplifying the current (I_{comparator1}, I_{comparator2}) over a predetermined duration of time, as described above. For example, in an alternative embodiment, the transistor (M4, M10) may be in the form of any switch circuit that selectively connects the second source/drain terminal of the transistor (M3, M9) to the second source/drain terminal of the transistor (M2, M8).

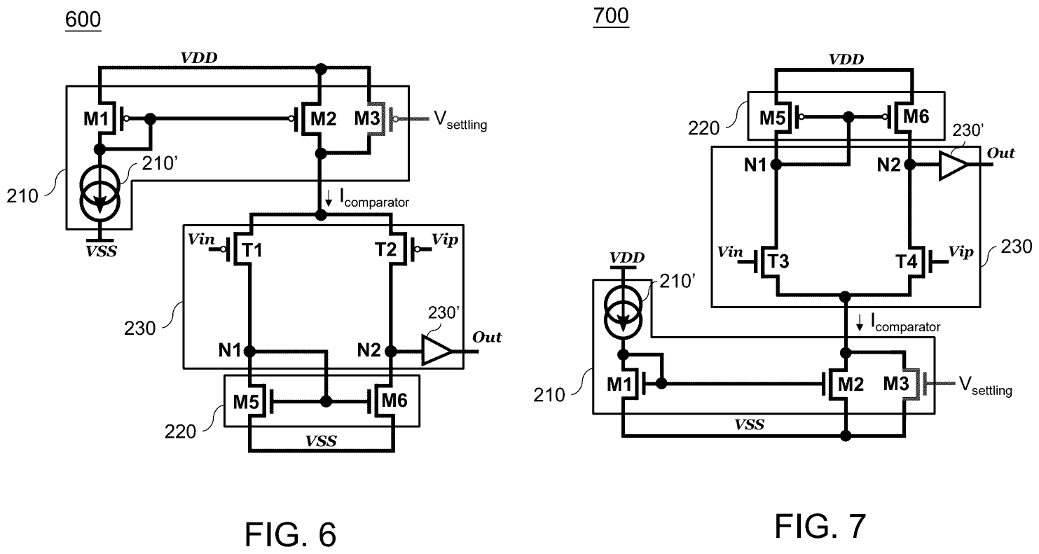

FIG. 6 is a schematic circuit diagram illustrating another exemplary device 600 in accordance with various embodiments of the present disclosure. As illustrated in FIG. 6, the example device 600 differs from the device 200 in that the current mirror circuit 210 of the device 600 is dispensed with the transistor (M4). In addition, the second source/drain terminal of the transistor (M3) is connected to the second source/drain terminal of the transistor (M2).

In operation, the device 600 receives the supply voltage (VDD). Consequently, the current source circuit 210′ generates a substantially constant current, whereby a transistor current flows through the transistor (M1). The transistor (M2) mirrors the transistor current flowing through the transistor (M1). Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). Thereafter, the buffer circuit 230′ generates an output voltage signal (Out) that indicates the result of comparison between the input voltage signal (Vin) and the reference voltage signal (Vip). At this time, the transistor (M3) is turned on by a settling voltage signal (V_{settling}). This amplifies (boosts or increases) the current (I_{comparator}) flowing to the comparator circuit 230 from an initial current value to a higher current value. The higher current value of the current (I_{comparator1}, I_{comparator2}) is maintained over a predetermined duration of time. As a result, the duration of the settling time it takes for the output voltage signal (Out) to stabilize and to provide an accurate comparison result is reduced, improving the efficiency of the device 600. After the predetermined duration of time elapses, the settling voltage signal (V_{settling}) goes high. This turns the transistor (M4) off, causing the current (I_{comparator}) to decrease back to its initial current value. Meanwhile, the device 600 continues with the comparison of the input voltage signal (Vin) to the reference voltage signal (Vip) and generates the output voltage signal (Out).

Although the current booster circuit of the device 600 is exemplified using a transistor (M3), the current booster circuit of the device 600 may take any form in other embodiments so long as it achieves the intended purpose of amplifying the current (I_{comparator}) over a predetermined duration of time, as described above.

FIG. 7 is a schematic circuit diagram illustrating an exemplary device 700 in accordance with various embodiments of the present disclosure. As illustrated in FIG. 7, the example device 700 differs from the device 600 in that the first source/drain terminal of the transistor (M1), the first source/drain terminal of the transistor (M2), and the first source/drain terminal of the transistor (M3) are connected to the supply voltage (Vss) (or an electrical ground). The current source circuit 210′ is connected between the second source/drain terminal of the transistor (M1) and the supply voltage (VDD). The first source/drain terminal of the transistor (M5) and the first source/drain terminal of the transistor (M6) are connected to the supply voltage (VDD).

Because the operations of the device 700 are similar to those described hereinabove in connection with the device 600, a detailed description of the same will be dispensed with herein for the sake of brevity.

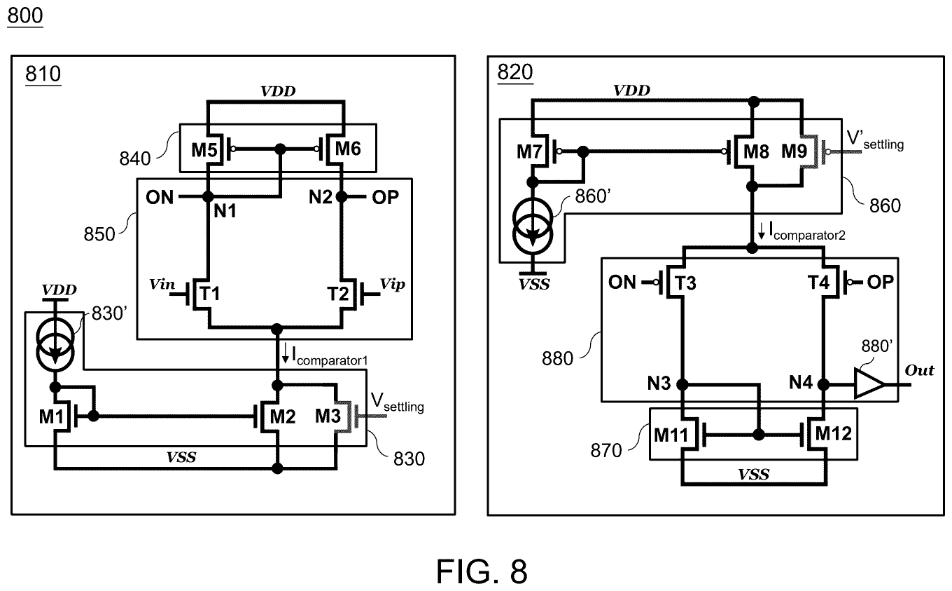

Although the device 600, 700 is exemplified as a single stage continuous-time comparator, multi-stage continuous-time comparators are also contemplated herein in other embodiments. For example, FIG. 8 is a schematic circuit diagram illustrating another exemplary device 800 in accordance with various embodiments of the present disclosure. As illustrated in FIG. 8, the example device 800 differs from the device 600 in that the device 800 is a two-stage continuous-time comparator and includes a first device stage 810 and a second device stage 820. In this exemplary embodiment, one of the first and second device stages 810, 820 has a high gain and the other of the first and second device stages 810, 820 is for limiting a bandwidth.

The first device stage 810 includes a current generator circuit, e.g., current generator circuit 120, and a comparator circuit 850. The current generator circuit includes a first current mirror circuit 830 and a second current mirror circuit 840. The first current mirror circuit 830 includes first-third transistors (M1-M3) and a current source circuit 830′. In this exemplary embodiment, the transistor (M3) is in the form of a current booster circuit configured to amplify (boost or increase) the current (I_{comparator1}) that flows to the comparator circuit 850.

Each transistor (M1-M3) is an NMOS transistor. The first source/drain terminal of the transistor (M1), the first source/drain terminal of the transistor (M2), and the first source/drain terminal of the transistor (M3) are connected to each other and to the supply voltage (Vss) (or electrical ground). The gate terminal of the transistor (M1) and the gate terminal of the transistor (M2) are connected to each other and to the second source/drain terminal of the transistor (M1). The current source circuit 830′ is connected between the second source/drain terminal of the transistor (M1) and the supply voltage (VDD).

The second current mirror circuit 840 includes transistors (M5, M6), each of which is a PMOS transistor. The first source/drain terminal of the transistor (M5) and the first source/drain terminal of the transistor (M6) are connected to each other and to the supply voltage (VDD). The gate terminal of the transistor (M5) and the gate terminal of the transistor (M6) are connected to each other and to the second source/drain terminal of the transistor (M5) at node (N1).

The comparator circuit 850 is connected between the first and second current mirror circuits 830, 840. For example, the comparator circuit 850 includes transistors (T1, T2), each of which is an NMOS transistor. The first source/drain terminal of the transistor (T1) and the first source/drain terminal of the transistor (T2) are connected to each other, to the second source/drain terminal of the transistor (M2), and to the second source/drain terminal of the transistor (M3). The second source/drain terminal of the transistor (T1) is connected to the node (N1). The gate terminal of the transistor (T1) serves as an inverted (or a non-inverted) input of the device 800. The second source/drain terminal of the transistor (T2) and the second source/drain terminal of the transistor (M6) are connected to each other at node (N2). The gate terminal of the transistor (T2) serves as a non-inverted (or an inverted) input of the device 800.

The second device stage 820 includes a current generator circuit, e.g., current generator circuit 120, and a comparator circuit 880. The current generator circuit includes a first current mirror circuit 860 and a second current mirror circuit 870. The first current mirror circuit 860 includes first-third transistors (M7-M9) and a current source circuit 860′. In this exemplary embodiment, the transistor (M9) is in the form of a current booster circuit configured to amplify (boost or increase) the current (I_{comparator2}) that flows to the comparator circuit 880.

Each transistor (M7-M9) is a PMOS transistor. The first source/drain terminal of the transistor (M7), the first source/drain terminal of the transistor (M8), and the first source/drain terminal of the transistor (M9) are connected to each other and to the supply voltage (VDD). The gate terminal of the transistor (M7) and the gate terminal of the transistor (M8) are connected to each other and to the second source/drain terminal of the transistor (M7). The current source circuit 860′ is connected between the second source/drain terminal of the transistor (M7) and the supply voltage (Vss) (or electrical ground).

The second current mirror circuit 870 includes transistors (M11, M12), each of which is an NMOS transistor. The first source/drain terminal of the transistor (M11) and the first source/drain terminal of the transistor (M12) are connected to each other and to the supply voltage (Vss) (or electrical ground). The gate terminal of the transistor (M11) and the gate terminal of the transistor (M12) are connected to each other and to the second source/drain terminal of the transistor (M11) at node (N3).

The comparator circuit 880 is connected between the first and second current mirror circuits 860, 870. For example, the comparator circuit 880 includes transistors (T3, T4) and a buffer circuit 880′. Each transistor (T3, T4) is a PMOS transistor. The first source/drain terminal of the transistor (T3) and the first source/drain terminal of the transistor (T4) are connected to each other, to the second source/drain terminal of the transistor (M8), and to the second source/drain terminal of the transistor (M9). The second source/drain terminal of the transistor (T3) is connected to the node (N3). The gate terminal of the transistor (T3) is connected to the node (N1). The second source/drain terminal of the transistor (T4) and the second source/drain terminal of the transistor (M12) are connected to each other at node (N4). The gate terminal of the transistor (T4) is connected to the node (N2). The buffer circuit 880′ has an input terminal connected to the node (N4) and an output terminal that serves as an output of the device 800.

In operation, the device 800 receives the supply voltage (VDD). Consequently, the current source circuits 830′, 860′ each generate a substantially constant current, whereby a transistor current flows through a respective transistor (M1, M7). The transistors (M2, M8) mirror the transistor currents through the transistors (M1, M7), respectively. Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). As a result, voltage signals (ON, OP), each of which corresponds to a respective one of the voltage signals (Vin, Vip), appear at the nodes (N1, N2), respectively.

Subsequently, the transistor (T3) receives the voltage signal (ON) at the gate terminal thereof, whereas the gate terminal of the transistor (T4) receives the voltage signal (OP). Next, the transistor (M11) generates a transistor current that flows therethrough and that is mirrored by the transistor (M12). Thereafter, the buffer circuit 880′ generates an output voltage signal (Out) that indicates the result of comparison between the input voltage signal (Vin) and the reference voltage signal (Vip). At this time, the transistors (M3, M9) are turned on by a settling voltage signal (V_{settling}) and an inverted version of the settling voltage signal (V_{settling}), respectively. This amplifies the current (I_{comparator1}, I_{comparator2}) flowing to the comparator circuit 850, 880 from an initial current value to a higher current value. The higher current value of the current (I_{comparator1}, I_{comparator2}) is maintained over a predetermined duration of time. As a result, the duration of the settling time it takes for the output voltage signal (Out) to stabilize and to provide an accurate comparison result is reduced, improving the efficiency of the device 800. After the predetermined duration of time elapses, the settling voltage signal V_{settling} goes low (and the inverted version of the settling voltage signal V_{settling} goes high). This turns the transistor (M3, M9) off, causing the current (I_{comparator1}, I_{comparator2}) to decrease back to its initial current value. Meanwhile, the device 800 continues with the comparison of the input voltage signal (Vin) to the reference voltage signal (Vip) and generates the output voltage signal (Out).

Although the current booster circuit of the device stage 810 is exemplified using a transistor (M3) and the current booster circuit of the device stage 820 is exemplified using a transistor (M9, M10), the current booster circuit of each device stage 810, 820 may take any form in other embodiments so long as it achieves the intended purpose of amplifying the current (I_{comparator1}, I_{comparator2}) over a predetermined duration of time, as described above.

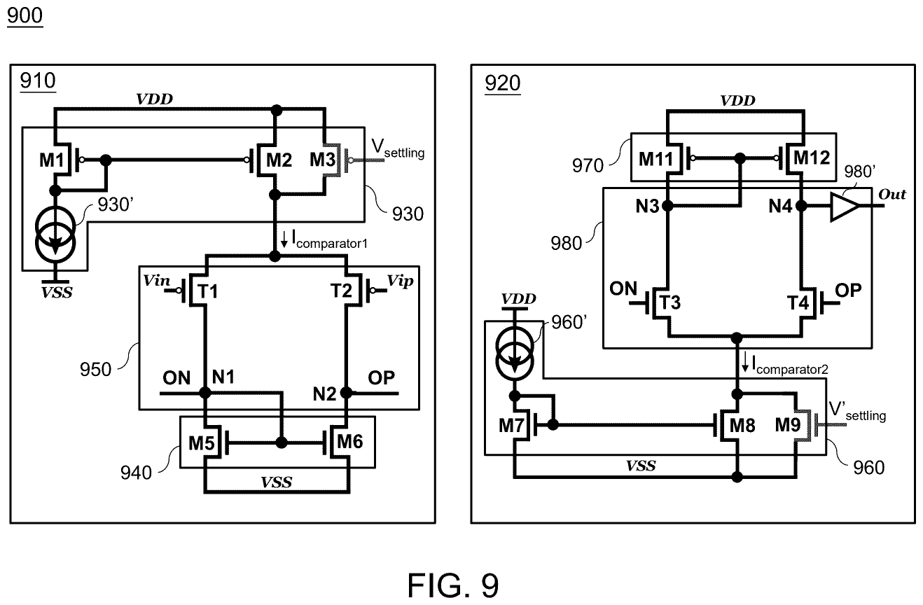

FIG. 9 is a schematic circuit diagram illustrating another exemplary device 900 in accordance with various embodiments of the present disclosure. As illustrated in FIG. 9, the example device 900 differs from the device 200 in that the device 900 is a two-stage continuous-time comparator and includes a first device stage 910 and a second device stage 920. In this exemplary embodiment, one of the first and second device stages 910, 920 has a high gain and the other of the first and second device stages 910, 920 is for limiting a bandwidth.

The first device stage 910 includes a current generator circuit, e.g., current generator circuit 120, and a comparator circuit 950. The current generator circuit includes a first current mirror circuit 930 and a second current mirror circuit 940. The first current mirror circuit 930 includes first-third transistors (M1-M3) and a current source circuit 930′. In this exemplary embodiment, the transistor (M3) is in the form of a current booster circuit configured to amplify (boost or increase) the current (I_{comparator1}) that flows to the comparator circuit 950.

Each transistor (M1-M3) is a PMOS transistor. The first source/drain terminal of the transistor (M1), the first source/drain terminal of the transistor (M2), and the first source/drain terminal of the transistor (M3) are connected to each other and to the supply voltage (VDD). The gate terminal of the transistor (M1) and the gate terminal of the transistor (M2) are connected to each other and to the second source/drain terminal of the transistor (M1). The current source circuit 930′ is connected between the second source/drain terminal of the transistor (M1) and the supply voltage (VSS) (or electrical ground).

The second current mirror circuit 940 includes transistors (M5, M6), each of which is an NMOS transistor. The first source/drain terminal of the transistor (M5) and the first source/drain terminal of the transistor (M6) are connected to each other and to the supply voltage (Vss) (or electrical ground). The gate terminal of the transistor (M5) and the gate terminal of the transistor (M6) are connected to each other and to the second source/drain terminal of the transistor (M5) at node (N1).

The comparator circuit 950 is connected between the first and second current mirror circuits 930, 940. For example, the comparator circuit 950 includes transistors (T1, T2), each of which is a PMOS transistor. The first source/drain terminal of the transistor (T1) and the first source/drain terminal of the transistor (T2) are connected to each other, to the second source/drain terminal of the transistor (M2), and to the second source/drain terminal of the transistor (M3). The second source/drain terminal of the transistor (T1) is connected to the node (N1). The gate terminal of the transistor (T1) serves as an inverted (or a non-inverted) input of the device 900. The second source/drain terminal of the transistor (T2) and the second source/drain terminal of the transistor (M6) are connected to each other at node (N2). The gate terminal of the transistor (T2) serves as a non-inverted (or an inverted) input of the device 900.

The second device stage 920 includes a current generator circuit, e.g., current generator circuit 120, and a comparator circuit 980. The current generator circuit includes a first current mirror circuit 960 and a second current mirror circuit 970. The first current mirror circuit 960 includes first-third transistors (M7-M9) and a current source circuit 960′. In this exemplary embodiment, the transistor (M9) is in the form of a current booster circuit configured to amplify (boost or increase) the current (I_{comparator2}) that flows to the comparator circuit 980.

Each transistor (M7-M9) is an NMOS transistor. The first source/drain terminal of the transistor (M7), the first source/drain terminal of the transistor (M8), and the first source/drain terminal of the transistor (M9) are connected to each other and to the supply voltage (VSS) (or electrical ground). The gate terminal of the transistor (M7) and the gate terminal of the transistor (M8) are connected to each other and to the second source/drain terminal of the transistor (M7). The current source circuit 960′ is connected between the second source/drain terminal of the transistor (M7) and the supply voltage (VDD).

The second current mirror circuit 970 includes transistors (M11, M12), each of which is a PMOS transistor. The first source/drain terminal of the transistor (M11) and the first source/drain terminal of the transistor (M12) are connected to each other and to the supply voltage (VDD). The gate terminal of the transistor (M11) and the gate terminal of the transistor (M12) are connected to each other and to the second source/drain terminal of the transistor (M11) at node (N3).

The comparator circuit 980 is connected between the first and second current mirror circuits 960, 970. For example, the comparator circuit 980 includes transistors (T3, T4) and a buffer circuit 980′. Each transistor is an NMOS transistor. The first source/drain terminal of the transistor (T3) and the first source/drain terminal of the transistor (T4) are connected to each other, to the second source/drain terminal of the transistor (M8), and to the second source/drain terminal of the transistor (M9). The second source/drain terminal of the transistor (T3) is connected to the node (N3). The gate terminal of the transistor (T3) is connected to the node (N1). The second source/drain terminal of the transistor (T4) and the second source/drain terminal of the transistor (M12) are connected to each other at node (N4). The gate terminal of the transistor (T4) is connected to the node (N2). The buffer circuit 980′ has an input terminal connected to the node (N4) and an output terminal that serves as an output of the device 900.

In operation, the device 900 receives the supply voltage (VDD). Consequently, the current source circuits 930′, 960′ each generate a substantially constant current, whereby a transistor current flows through a respective transistor (M1, M7). The transistors (M2, M8) mirror the transistor currents through the transistors (M1, M7), respectively. Then, the transistor (T1) receives an input voltage signal (Vin) at the gate terminal thereof, whereas the gate terminal of the transistor (T2) receives a reference voltage signal (Vip). Next, the transistor (M5) generates a transistor current that flows therethrough and that is mirrored by the transistor (M6). As a result, voltage signals (ON, OP), each of which corresponds to a respective one of the voltage signals (Vin, Vip), appear at the nodes (N1, N2), respectively.

Subsequently, the transistor (T3) receives the voltage signal (ON) at the gate terminal thereof, whereas the gate terminal of the transistor (T4) receives the voltage signal (OP). Next, the transistor (M11) generates a transistor current that flows therethrough and that is mirrored by the transistor (M12). Thereafter, the buffer circuit 980′ generates an output voltage signal (Out) that indicates the result of comparison between the input voltage signal (Vin) and the reference voltage signal (Vip). At this time, each transistor (M4, M10) are turned on by a settling voltage signal (V_{settling}) and an inverted version of the settling voltage signal (V_{settling}), respectively. This amplifies the current (I_{comparator1}, I_{comparator2}) flowing to the comparator circuit 950, 980 from an initial current value to a higher current value. The higher current value of the current (I_{comparator1}, I_{comparator2}) is maintained over a predetermined duration of time. As a result, the duration of the settling time it takes for the output voltage signal (Out) to stabilize and to provide an accurate comparison result is reduced, improving the efficiency of the device 900. After the predetermined duration of time elapses, the settling voltage signal V_{settling} goes high (and the inverted version of the settling voltage signal V_{settling} goes low). This turns the transistor (M3, M9) off, causing the current (I_{comparator1}, I_{comparator2}) to decrease back to its initial current value. Meanwhile, the device 900 continues with the comparison of the input voltage signal (Vin) to the reference voltage signal (Vip) and generates the output voltage signal (Out).

Although the current booster circuit of the device stage 910 is exemplified using a transistor (M3) and the current booster circuit of the device stage 920 is exemplified using a transistor (M9), the current booster circuit of each device stage 510, 520 may take any form in other embodiments so long as it achieves the intended purpose of amplifying the current (I_{comparator1}, I_{comparator2}) over a predetermined duration of time, as described above.

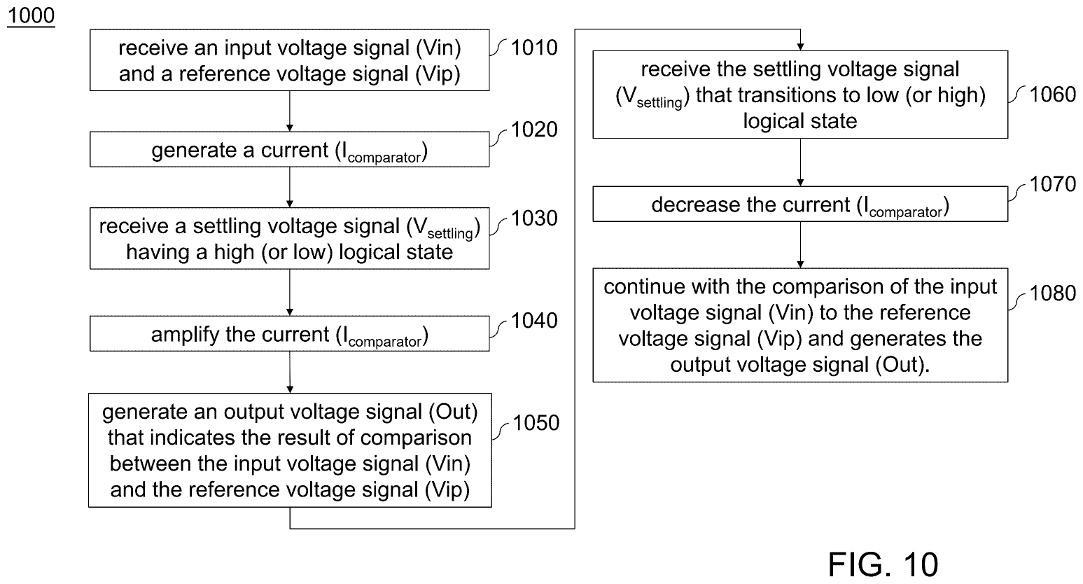

FIG. 10 is a flowchart of an exemplary method 1000 for reducing a settling time of an output voltage signal of a device in accordance with various embodiments of the present disclosure. The example method 1000 will now be described with further reference to FIGS. 1-3, 6, and 7 for ease of understanding. It is understood that the method 1000 is applicable to structures other than those of FIGS. 1-3, 6, and 7. Further, it is understood that additional operations can be provided before, during, and after the method 1000, and some of the operations described below can be replaced or eliminated, in an alternative embodiment of the method 1000.

In operation 1010, the comparator circuit 110 receives an input voltage signal (Vin) and a reference voltage signal (Vip). In operation 1020, the current generator circuit 120 generates a current (I_{comparator}) that flows to the comparator circuit 110. In operation 1030, the current generator circuit 120 receives a settling voltage signal (V_{settling}) having, e.g., a high (or low) logical state. In operation 1040, the current generator circuit 120 amplifies the current (I_{comparator}) from an initial current value to a higher current value. The higher current value of the current (I_{comparator}) is maintained over a predetermined duration of time. In operation 1050, the comparator circuit 110 generates an output voltage signal that indicates the result of comparison between the input voltage signal (Vin) and the reference voltage signal (Vip).

In operation 1060, after a predetermined duration of time, the current generator circuit 120 receives the settling voltage signal (V_{settling}) that transitions from a high (or low) logical state to a low (or high) logical state. In operation 1070, the current generator circuit 120 decreases back the current (I_{comparator}) to its initial current value. In operation 1080, the comparator circuit 110 continues with the comparison of the input voltage signal (Vin) to the reference voltage signal (Vip) and generates the output voltage signal (Out).

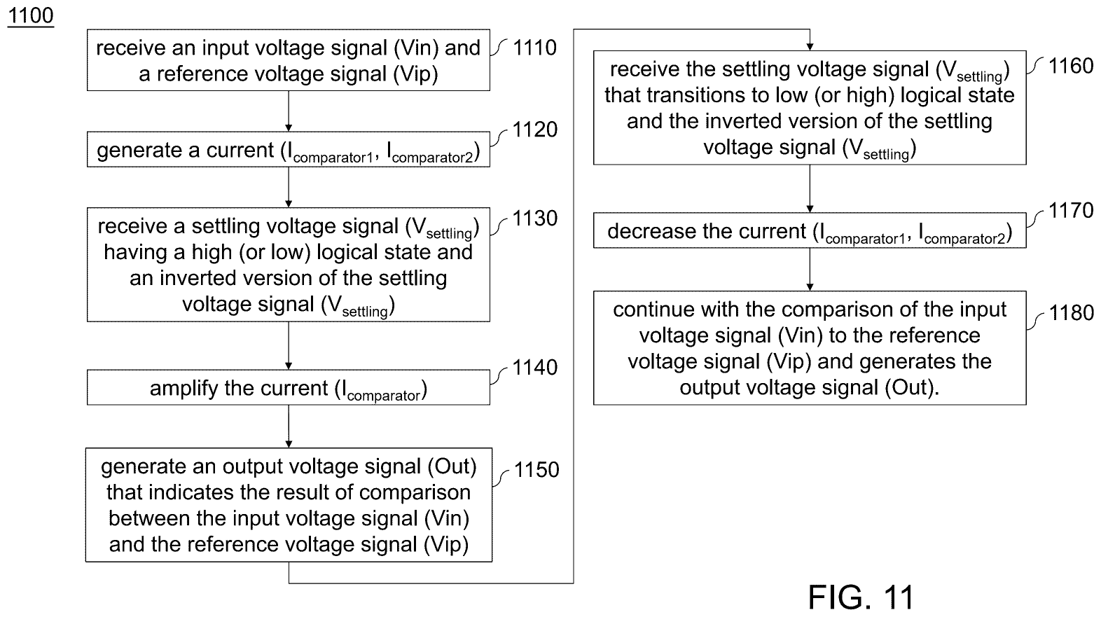

FIG. 11 is a flowchart of an exemplary method 1100 of reducing a settling time of an output voltage signal of a device in accordance with various embodiments of the present disclosure. The example method 1000 will now be described with further reference to FIGS. 1, 4, 5, 8, and 9 for ease of understanding. It is understood that the method 11 is applicable to structures other than those of FIGS. 1, 4, 5, 8, and 9. Further, it is understood that additional operations can be provided before, during, and after the method 1100, and some of the operations described below can be replaced or eliminated, in an alternative embodiment of the method 1100.

In operation 1110, the comparator circuit 110 receives an input voltage signal (Vin) and a reference voltage signal (Vip). In operation 1120, the current generator circuit 120 generates a current (I_{comparator1}, I_{comparator2}) that flows to the comparator circuit 110. In operation 1030, the current generator circuit 120 receives a settling voltage signal (V_{settling}) having, e.g., a high (or low) logical state, and an inverted version of the settling voltage signal (V_{settling}). In operation 1040, the current generator circuit 120 amplifies the current (I_{comparator1}, I_{comparator2}) from an initial current value to a higher current value. The higher current value of the current (I_{comparator1}, I_{comparator2}) is maintained over a predetermined duration of time. In operation 1050, the comparator circuit 110 generates an output voltage signal that indicates the result of comparison between the input voltage signal (Vin) and the reference voltage signal (Vip).

In operation 1060, after a predetermined duration of time, the current generator circuit 120 receives the settling voltage signal (V_{settling}) that transitions from a high (or low) logical state to a low (or high) logical state and an inverted version of the settling voltage signal (V_{settling}) that transitions from a low (or high) logical state to a high (or low) logical state. In operation 1070, the current generator circuit 120 decreases back the current (I_{comparator1}, I_{comparator2}) to its initial current value. In operation 1080, the comparator circuit 110 continues with the comparison of the input voltage signal (Vin) to the reference voltage signal (Vip) and generates the output voltage signal (Out).

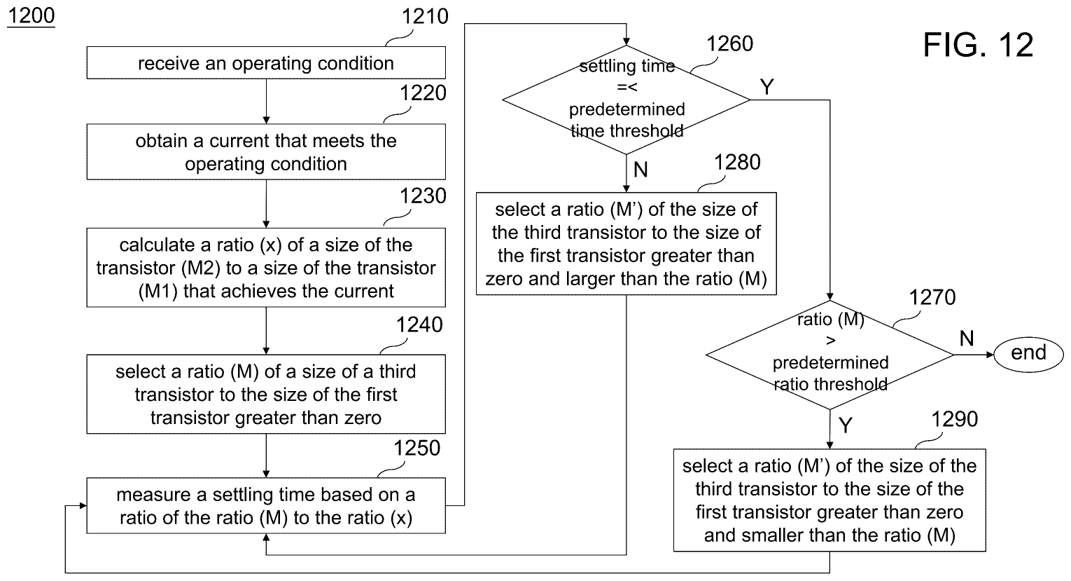

FIG. 12 is a flowchart illustrating an exemplary method 1200 of designing a device in accordance with various embodiments of the present disclosure. The example method 1200 will now be described with further reference to FIGS. 1-9 for ease of understanding. It is understood that the method 1200 is applicable to structures other than those of FIGS. 1-9. Further, it is understood that additional operations can be provided before, during, and after the method 1200, and some of the operations described below can be replaced or eliminated, in an alternative embodiment of the method 1200.

In operation 1210, the circuit design system or engineer receives one or more operating conditions, e.g., bandwidth, gain, topology, common mode, resolution, input range, and the like, of the device 100. In operation 1220, the circuit design system or engineer obtains a current that meets the one or more operating conditions received thereby. In operation 1230, the circuit design system or engineer calculates a ratio (x) of a size (e.g., width or length of a channel) of the transistor (M2),to a size of the transistor (M1) that achieves the current obtained thereby. In operation 1240, the circuit design system or engineer selects a ratio (M) of a size of the transistor (M3) to the size of the transistor (M1) greater than zero. In certain embodiments, the circuit design system or engineer calculates the ratio (M) based on a predetermined specification, e.g., power, area, and/or speed, of the device.

In operation 1250, the circuit design system or engineer measures a settling time, which is a duration it takes for the output voltage signal (Out) of the device 100 to stabilize and to provide an accurate comparison result, based on a ratio of the ratio (M) to the ratio (x). In certain embodiments, the circuit design system or engineer measures an additional current and/or a speed of the device based on the ratio of the ratio (M) to the ratio (x).

In operation 1260, when it is determined, by the circuit design system or engineer, that the settling time measured thereby is equal or less than a predetermined time threshold, the flow proceeds to operation 1270. Otherwise, the flow proceeds to operation 1280. In operation 1270, when it is determined, by the circuit design system or engineer, that the ratio (M) is equal or greater than the predetermined ratio threshold, the flow proceeds to operation 1290. Otherwise, i.e., it is determined that the ratio (M) is less than the predetermined ratio threshold, the flow goes back to operation 1250.

In an embodiment, a device comprises a comparator circuit and a current generator circuit. The comparator circuit, responsive to a current, receives an input signal and a reference signal, compares the input signal with the reference signal, and generates an output signal that indicates the result of comparison. The current generator circuit includes a current mirror circuit and a current booster circuit. The current mirror circuit generates the current. The current booster circuit amplifies the current from an initial current value to a higher current value and maintains the current at the higher current value over a predetermined duration of time.

In another embodiment, a device comprises first and second comparator circuits and first and second current generator circuits. The first comparator circuit, responsive to a first current, receives an input signal and a reference signal, compares the input signal with the reference signal, and generates a first output signal that corresponds to the input signal and a second output signal that corresponds to the reference signal. The first current generator circuit includes a first current mirror circuit and a first current booster circuit. The first current mirror circuit generates the first current. The first current booster circuit amplifies the first current from a first initial current value to a first higher current value and maintains the first current at the first higher current value over a predetermined duration of time. The second comparator circuit, responsive to a second current, receives the first and second output signals, compares the first output signal with the second output signal, and generates a third output signal that indicates the result of comparison. The second current generator circuit includes a second current mirror circuit and a second current booster circuit. The second current mirror circuit generates the second current. The second current booster circuit amplifies the second current from a second initial current value to a second higher current value and maintains the second current at the second higher current value over the predetermined duration of time.

In another embodiment, a method for reducing a settling time of an output of a comparator comprises: receiving an input signal and a reference signal; in response to a current, comparing the input signal with the reference signal; generating an output signal that indicates the result of comparison; amplifying the current from an initial current value to a higher current value; and maintaining the current at the higher current value over a predetermined duration of time.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a comparator circuit, responsive to a current, that is configured to receive an input signal and a reference signal, to compare the input signal with the reference signal, and to generate an output signal that indicates the result of comparison; and
a current generator circuit including:
a first current mirror circuit configured to generate the current; and
a current booster circuit configured to amplify the current from an initial current value to a higher current value and to maintain the current at the higher current value over a predetermined duration of time.

2. The device of claim 1, wherein:
the first current mirror circuit includes:
a first transistor configured to generate a transistor current therethrough; and
a second transistor configured to mirror the transistor current; and
the current booster circuit includes a third transistor and a fourth transistor connected in series with the third transistor, wherein the third and fourth transistors are connected in parallel with the second transistor.

3. The device of claim 2, further comprising a current source circuit configured to generate a substantially constant current and connected in series with the first transistor, wherein the series connection of the first transistor and the current source circuit is connected across a first supply voltage and a second supply voltage or electrical ground.

4. The device of claim 3, wherein:
the first transistor is connected between the first supply voltage and the current source circuit; and
the current source circuit is connected between the first transistor and the second supply voltage or electrical ground.

5. The device of claim 3, wherein:
the current source circuit is connected between the first supply voltage and the first transistor; and
the first transistor is connected between the current source circuit and the second supply voltage or electrical ground.

6. The device of claim 1, further comprising a second current mirror circuit, wherein the comparator circuit is connected between the first and second current mirror circuits.

7. The device of claim 1, wherein:
the first current mirror circuit is connected between a first supply voltage and the comparator circuit; and
the second current mirror circuit is connected between a second supply voltage or electrical ground and the comparator circuit.

8. The device of claim 1, wherein:
the second current mirror circuit is connected between a first supply voltage and the comparator circuit; and
the first current mirror circuit is connected between a second supply voltage or electrical ground and the comparator circuit.

9. (canceled)

10. A device comprising:
a first comparator circuit, responsive to a first current, that is configured to receive an input signal and a reference signal, to compare the input signal with the reference signal, and to generate a first output signal that corresponds to the input signal and a second output signal that corresponds to the reference signal;
a first current generator circuit including:
a first current mirror circuit configured to generate the first current; and
a first current booster circuit configured to amplify the first current from a first initial current value to a first higher current value and to maintain the first current at the first higher current value over a predetermined duration of time;
a second comparator circuit, responsive to a second current, that is configured to receive the first and second output signals, to compare the first output signal with the second output signal, and to generate a third output signal that indicates the result of comparison; and
a second current generator circuit including:
a second current mirror circuit configured to generate the second current; and
a second current booster circuit configured to amplify the second current from a second initial current value to a second higher current value and to maintain the second current at the second higher current value over the predetermined duration of time.

11. The device of claim 10, wherein:
the first current mirror circuit includes:
a first transistor configured to generate a transistor current therethrough; and
a second transistor configured to mirror the transistor current; and
the first current booster circuit includes a third transistor and a fourth transistor connected in series with the third transistor, wherein the third and fourth transistors are connected in parallel with the second transistor.

12. The device of claim 10, further comprising a third current mirror circuit connected between a first supply voltage and the first comparator circuit, wherein the first current mirror circuit is connected between the first comparator circuit and a second supply voltage or electrical ground.

13. The device of claim 10, wherein the second current mirror circuit is connected between a first supply voltage and the second comparator circuit, wherein the device further comprising a third current mirror circuit connected between the second comparator circuit and a second supply voltage or electrical ground.

14. The device of claim 10, wherein the first current mirror circuit is connected between a first supply voltage and the first comparator circuit, wherein the device further comprising a third current mirror circuit connected between the first comparator circuit and a second supply voltage or electrical ground.

15. The device of claim 10, further comprising a third current mirror circuit connected between a first supply voltage and the second comparator circuit, wherein the second current mirror circuit is connected between the second comparator circuit and a second supply voltage or electrical ground.

16. (canceled)

17. A method comprising:
receiving an input signal and a reference signal;
in response to a current, comparing the input signal with the reference signal;
generating an output signal that indicates the result of comparison;
amplifying the current from an initial current value to a higher current value; and
maintaining the current at the higher current value over a predetermined duration of time.

18. The method of claim 17, further comprising:
generating, by a first transistor, a transistor current;
mirroring, by a second transistor, the transistor current; and
in response to a settling signal, connecting a series connection of third and fourth transistors in parallel with the second transistor.

19. (canceled)

20. The method of claim 17, further comprising:
generating, by a first transistor, a transistor current;
generating, by a current source circuit connected in series with the first transistor, a current having a substantially constant current value; and
mirroring, by a second transistor, the transistor current.

21. The device of claim 2, wherein a gate terminal of the fourth transistor is configured to receive a settling voltage signal to amplify the current.

22. The device of claim 12, wherein the third current mirror includes a fifth transistor and a sixth transistor, gate terminals of the fifth and sixth transistors are connected to each other and to a source/drain terminal of the fifth transistor.

23. The method of claim 18, wherein a gate terminal of the fourth transistor is configured to receive the settling signal to amplify the current.
